(19) United States
(12) Patent Application Publication
(10) Pub. No.: US 2026/0324518 A1
(43) Pub. Date: Oct. 15, 2026

(54) MODULAR INTERCONNECTION DEVICE AND A METHOD FOR FORMING THE SAME

(71) Applicant: JCET STATS ChipPAC Korea Limited, Incheon (KR)

(72) Inventors: SeungHyun LEE, Incheon (KR); YeoJun YUN, Incheon (KR); YeJin PARK, Incheon (KR); HeeSoo LEE, Incheon (KR)

(21) Appl. No.: 19/642,675

(22) Filed: Apr. 9, 2026

(30) Foreign Application Priority Data
Apr. 10, 2025 (CN) 202510444024.4

(51) Int. Cl. H10W 90/00; H10W 42/20; H10W 70/00; H10W 72/00; H10W 90/10; H10W 90/22; H10W 74/01

(52) U.S. Cl. CPC H10W 90/401; H10W 42/276; H10W 70/099; H10W 72/823; H10W 90/10; H10W 90/22; H10W 74/014

(57) ABSTRACT

A modular interconnection device and a method for forming the same are provided. The modular interconnection device comprises: a first interconnection layer having a first insulating layer and a first plurality of preformed conductive pillars extending vertically through the first insulating layer; and a second interconnection layer formed on the first interconnection layer, the second interconnection layer having a second insulating layer and a second plurality of preformed conductive pillars extending through the second interconnection layer, wherein the second interconnection layer further has at least one electronic component formed within the second insulating layer and electrically connected with a first subset of the first plurality of preformed conductive pillars, and wherein the second plurality of preformed conductive pillars are aligned vertically and electrically connected with a second subset of the first plurality of preformed conductive pillars.

### TECHNICAL FIELD

The present application generally relates to semiconductor technology, and more particularly, to a modular interconnection device and a method for forming the same.

### BACKGROUND OF THE INVENTION

The semiconductor industry is constantly faced with complex integration challenges as consumers want their electronics to be smaller, faster and higher performance with more and more functionalities packed into a single device. A typical type of packaging method is combining two or more integrated circuit (IC) modules together. To be more specific, two or more IC modules such as IC packages are vertically connected and stacked via vertical interconnection units (such as e-bars) that can direct signals between them, thereby forming an integrated electronic assembly. The integrated electronic assembly can more efficiently use space, and reduce lengths of signal paths between the packages. Thus, a better electrical performance can be achieved, as the shorter signal path length may reduce noises and cross talks in integrated circuits and promote faster signal response. However, the existing integration level of the electronic assembly remains unsatisfactory.

Therefore, a need exists for an interconnection device which improves an integration level of an electronic package.

### SUMMARY OF THE INVENTION

An objective of the present application is to provide an interconnection device which improves an integration level of an electronic package, and a method for forming the interconnection device.

According to an aspect of the present application, a modular interconnection device is provided. The modular interconnection device comprises: a first interconnection layer having a first insulating layer and a first plurality of preformed conductive pillars extending vertically through the first insulating layer with respective bottom surfaces exposed from a bottom surface of the first insulating layer; and a second interconnection layer formed on a top surface of the first interconnection layer, the second interconnection layer having a second insulating layer and a second plurality of preformed conductive pillars extending through the second interconnection layer with respective top surfaces exposed from a top surface of the second insulating layer, wherein the second interconnection layer further has at least one electronic component formed within the second insulating layer and electrically connected with a first subset of the first plurality of preformed conductive pillars, and wherein the second plurality of preformed conductive pillars are aligned vertically and electrically connected with a second subset of the first plurality of preformed conductive pillars.

According to another aspect of the present application, a method for forming a modular interconnection device is provided. The method comprises: providing a carrier; attaching a first plurality of preformed conductive pillars on a front surface of the carrier; forming a first molding layer on the carrier to encapsulate the first plurality of preformed conductive pillars but expose their respective bottom surfaces; mounting at least one electronic component onto a first subset of the first plurality of preformed conductive pillars; vertically aligning and connecting a second plurality of preformed conductive pillars with a second subset of the first plurality of preformed conductive pillars; and forming a second molding layer on the first molding layer to encapsulate the second plurality of preformed conductive pillars and the at least one electronic component but expose respective front surfaces of the second plurality of preformed conductive pillars.

According to another aspect of the present application, a method for forming a modular interconnection device is provided. The method comprises: providing a substrate having a substrate base and a first plurality of preformed conductive pillars extending vertically through the substrate base with respective bottom surfaces exposed from a bottom surface of the substrate base; mounting at least one electronic component onto a first subset of the first plurality of preformed conductive pillars; vertically aligning and connecting a second plurality of preformed conductive pillars with a second subset of the first plurality of preformed conductive pillars; and forming a molding layer on the substrate to encapsulate the second plurality of preformed conductive pillars and the at least one electronic component but expose respective front surfaces of the second plurality of preformed conductive pillars.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A-1K illustrate various steps of a method for forming a modular interconnection device according to a first embodiment of the present application.

FIGS. 2A-2G illustrate various steps of a method for forming a modular interconnection device according to a second embodiment of the present application.

FIGS. 3A-3G illustrate various steps of a method for forming an electronic package assembly according to a third embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, electronic modules can be vertically connected and stacked via vertical interconnection units that can direct signals between them, thereby forming an integrated electronic package. A typical type of a vertical interconnection unit may be an e-bar module, which includes built-in conductive pillars and an insulative base material isolating the conductive pillars from each other. However, the integration level of the electronic package with conventional e-bars remain unsatisfactory. Furthermore, for large-scale electronic modules with greater thicknesses, establishing reliable electronic connection between them via conventional e-bars may cause performance challenges due to inefficient space utilization and complicated processing required for tall e-bar modules.

To address the above issue, a modular interconnection device is provided. The modular interconnection device includes a first interconnection layer having a first insulating layer and a first plurality of preformed conductive pillars extending vertically through the first insulating layer. The modular interconnection device further includes a second interconnection layer formed on the first interconnection layer. The second interconnection layer has a second insulating layer, a second plurality of preformed conductive pillars extending through the second interconnection layer and at least one electronic component formed within the second insulating layer. The second plurality of preformed conductive pillars and the at least one electronic component are both electrically connected with the first plurality of preformed conductive pillars. Since the preformed conductive pillars are formed in two layers of the modular interconnection device instead of being fabricated as taller integrated pieces, their formation process may be more convenient and cost-effective. Furthermore, the modular interconnection device includes at least one electronic component formed within the second insulating layer. This allows for more efficient space utilization of the modular interconnection device by integrating additional functionality through the embedded electronic component(s) apart from electrical interconnections. As a result, the integration level of an electronic package utilizing this modular interconnection device can be significantly improved, and the electrical performance may also be enhanced.

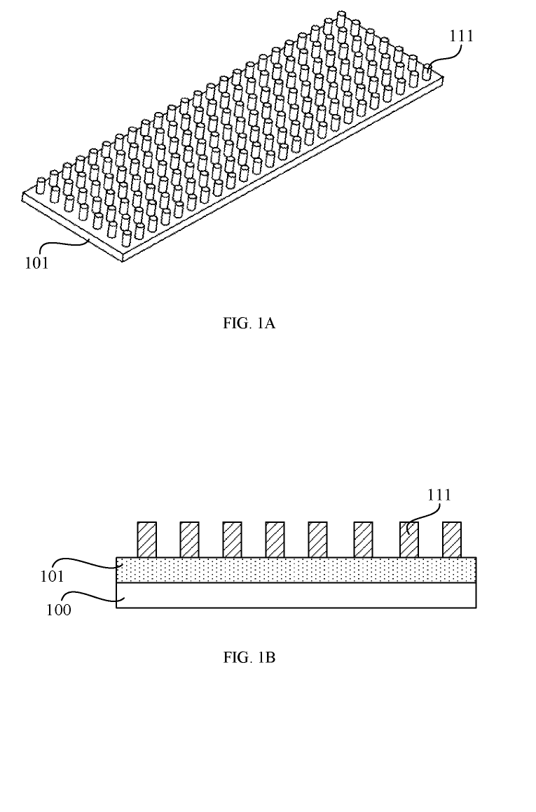

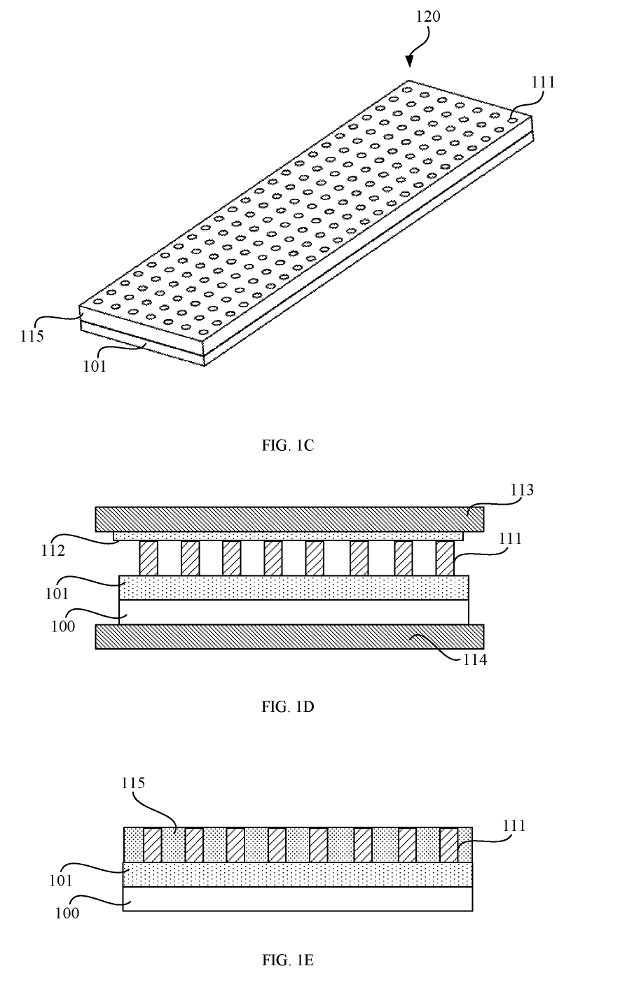

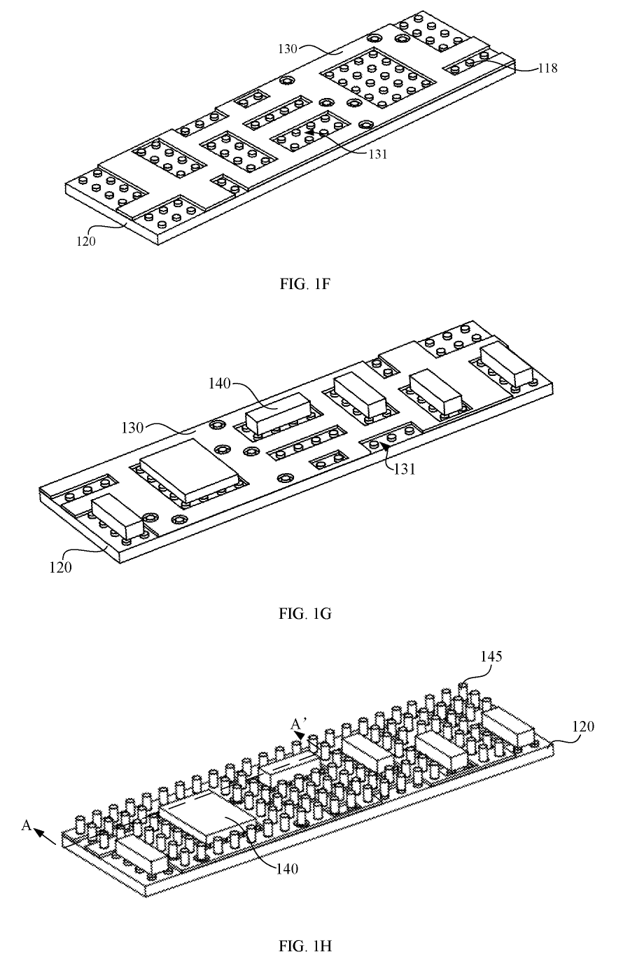

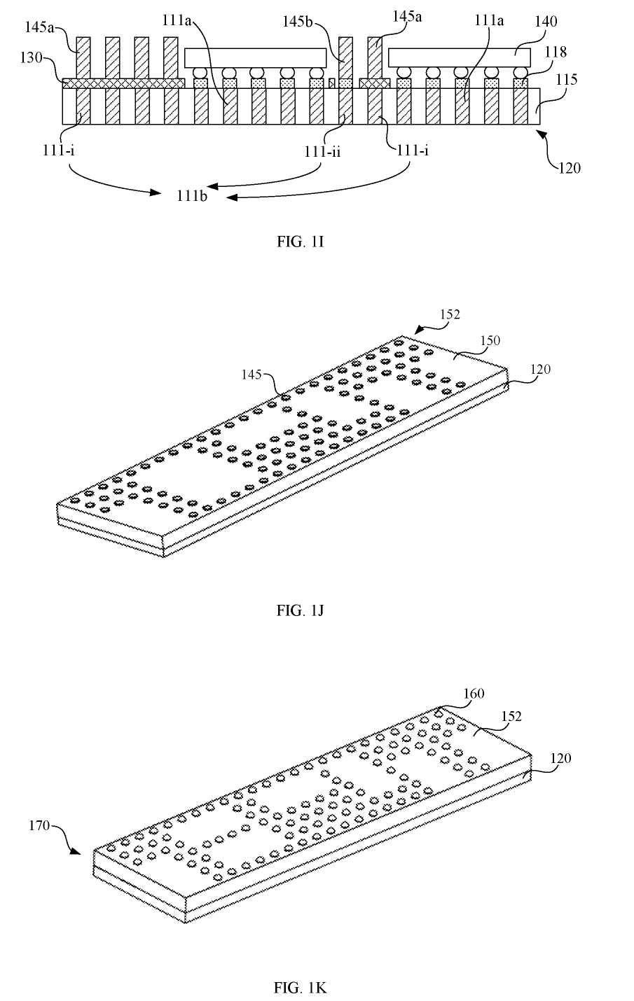

FIGS. 1A-1K illustrate various steps of a method for forming a modular interconnection device according to a first embodiment of the present application. The modular interconnection device formed using the method is shown in FIG. 1K.

As shown in FIGS. 1A and IB, a carrier 100 is provided as a platform for forming a modular interconnection device. Next, an adhesive layer 101 is attached onto a top surface of the carrier 100. A first plurality of conductive pillars 111 are attached onto a front surface of the adhesive layer 101, which are in turn attached onto a front surface of the carrier 100. In particular, FIG. 1A illustrates a perspective view of the adhesive layer 101 and the conductive pillars 111. It should be noted that the carrier 100 is omitted in FIG. 1A for simplicity. FIG. 1B illustrates a sectional view of the adhesive layer 101 and the conductive pillars 111, as well as the carrier 100 underneath the adhesive layer 101.

In some embodiments, the adhesive layer 101 may be a sticky tape that allows attachment of the conductive pillars 111 with the carrier 100. The adhesive layer 101 may be easily removed to separate the structures formed thereon from the carrier 100. In some embodiments, the adhesive layer 101 may be an ultraviolet (UV) sensitive tape. The UV sensitive tape may be adhesive after being applied onto the carrier 100, and then be hardened after irradiation by UV light with a certain wavelength range. In this way, the tape can be easily removed from the formed structures.

In some embodiments, the first plurality of conductive pillars 111 are preformed in a batch manner, for example. In some embodiments, the first plurality of preformed conductive pillars 111 may have a cylindrical shape. In some other embodiments, the first plurality of preformed conductive pillars 111 may have other shapes, for example, the first plurality of preformed conductive pillars 111 may have a cross section of a rectangle, a hexagon or an octagon. In some other embodiments, the first plurality of preformed conductive pillars 111 may be metal pillars, or particularly, copper pillars.

As shown in FIGS. 1A and 1B, the first plurality of preformed conductive pillars 111 are parallel to each other as they are generally all extending upward from the carrier 100. To be more specific, the first plurality of preformed conductive pillars 111 may be arranged in an array configuration including columns and rows. In some embodiments, the carrier 100 may include a plurality of slots on its front surface, and each of the slots can be used for receiving a bottom portion of one of the first plurality of preformed conductive pillars 111. In this way, the first plurality of preformed conductive pillars 111 may be fixed in place with the carrier 100 without undesired lateral movement or tilting. Also, the slots on the carrier 100 may help to position the first plurality of preformed conductive pillars 111 more conveniently and accurately. In some alternative embodiments, a plurality of sticks may be disposed on the front surface of the adhesive layer 101. The plurality of sticks may be arranged in a grid configuration with intersecting columns and rows, forming multiple openings between them. The first plurality of preformed conductive pillars 111 can be positioned within the multiple openings to attach themselves onto the adhesive layer 101. As such, each of the first plurality of preformed conductive pillars 111 can be surrounded by multiple sticks in different directions such that the first plurality of preformed conductive pillars 111 can be fixed in place. In some further embodiments, a frame with a mesh pattern may be disposed onto the adhesive layer 101. The mesh pattern may include a plurality of openings for receiving the first plurality of preformed conductive pillars 111, respectively. The frame may include a material which is generally used as a molding material, for example, a polymer composite material, such as epoxy resin with filler, epoxy acrylate with filler, or polymer with proper filler, but the scope of this application is not limited thereto. Since the frame may have a same material as a first molding layer formed subsequently which encapsulates the first plurality of preformed conductive pillars 111, the frame may remain embedded within and become a part of the first molding layer (as described below).

Next, as shown in FIG. 1C, the first insulating layer is formed on the carrier 100 and the adhesive layer 101. In particular, in this embodiment, the first insulating layer may be a first molding layer 115. The first molding layer 115 encapsulates the first plurality of preformed conductive pillars 111. Bottom surfaces of the first plurality of preformed conductive pillars 111 are exposed from a bottom surface of the first molding layer 115. In particular, a film assisted molding may be implemented to form the first molding layer 115. The details of the formation of the first molding layer 115 are illustrated in FIGS. 1D and 1E, which are sectional views showing the molding process.

As shown in FIG. 1D, a top chase 113 and a bottom chase 114 are provided to conduct the film assisted molding process. The top chase 113 is attached onto the top surfaces of the first plurality of preformed conductive pillars 111, and the bottom chase 114 is attached onto a bottom surface of the carrier 100. The top chase 113 and the bottom chase 114 form a chamber in which the carrier 100, the adhesive layer 101 and the first plurality of preformed conductive pillars 111 are accommodated. In some embodiments, a flexible film 112 may be attached onto a bottom of the top chase 113 and may be in contact with the first plurality of preformed conductive pillars 111. The flexible film 112 may deform to accommodate respective top portions of the first plurality of preformed conductive pillars 111. In this way, the first plurality of preformed conductive pillars 111 may not be tilted, moved or damaged during the molding process. In addition, the top chase 113 may provide a compressive force to fix the first plurality of preformed conductive pillars 111 in place. In some embodiments, the top chase 113 may be pressed against the bottom chase 114 via an external force to make sure the top surfaces of the first plurality of preformed conductive pillars 111 are flush with each other to avoid undesired tilting. Next, a molding material may be filled into the chamber between the top chase 113 and the bottom chase 114 to form the first molding layer 115. As shown in FIGS. 1C and 1E, the first molding layer 115 encapsulates the first plurality of preformed conductive pillars 111 but expose their respective top and bottom surfaces. As such, the first interconnection layer 120 is formed, which includes the first molding layer 115 and the first plurality of preformed conductive pillars 111 extending vertically through the first molding layer 115.

In some embodiments, the first molding layer 115 may be made of a polymer composite material, such as epoxy resin with filler, epoxy acrylate with filler, or polymer with proper filler, but the scope of this application is not limited thereto.

Next, the adhesive layer 101 and the carrier 100 are removed to separate the first interconnection layer 120 from the carrier 100.

Next, as shown in FIG. 1F, a patterned shielding layer 130 is formed on the first interconnection layer 120. The patterned shielding layer 130 includes a plurality of openings 131 exposing a portion of the first plurality of preformed conductive pillars 111. To be more specific, the patterned shielding layer 130 may be formed using following steps. A conductive material may be deposited on a front surface of the first interconnection layer 120. Next, a mask layer (e.g., a photoresist layer) with openings passing therethrough may be formed on a front surface of the conductive material to define a pattern of the openings 131 within the patterned shielding layer 130. Then an etching process may be conducted using the mask layer to remove a portion of the conductive material to form the plurality of openings 131 within the conductive material, thereby forming the patterned shielding layer 130. It can also be appreciated that the openings 131 may be formed using laser ablation, milling, drilling, pinching or their combinations. In this way, the patterned shielding layer 130 is in direct contact with and electrically connected with a portion of the first plurality of preformed conductive pillars 111. In addition, the openings 131 of the shielding layer expose a remaining portion of the first plurality of preformed conductive pillars 111, which correspond to a layout of electronic component(s) and conductive pillars to be mounted thereon. In some embodiments, materials used for the patterned shielding layer 130 may include metals, carbons, conducting polymers, etc.

Furthermore, a first plurality of conductive pads 118 may be formed on the top surfaces of the first plurality of preformed conductive pillars 111. It can also be appreciated that the first plurality of conductive pads 118 may be exp osed portions of the first plurality of preformed conductive pillars 111.

In some embodiments, the patterned shielding layer 130 may be connectable to a reference voltage, such as being grounded, thereby blocking electromagnetic interference from propagating into the modular interconnection device.

Next, as shown in FIG. 1G, at least one electronic component 140 is mounted onto a first subset of the first plurality of preformed conductive pillars 111. The at least one electronic component 140 includes resistors, capacitors or other passive components, or semiconductor dice, integrated circuit chips, small semiconductor packages or pre-molded electronic packages. Each of the electronic component(s) 140 is attached onto the exposed first plurality of preformed conductive pillars 111 through one of the openings 131 of the patterned shielding layer 130. In this way, the at least one electronic component 140 may be electrically connected with the first subset of the first plurality of preformed conductive pillars 111. In addition, the at least one electronic component 140 may include solder bumps on its back surface for mounting it onto the first subset of the first plurality of preformed conductive pillars 111. In some embodiments, multiple electronic components 140 are mounted onto the first subset of the first plurality of preformed conductive pillars 111 through the openings 131 of the patterned shielding layer 130. However, only a portion of the openings 131 are occupied by the electronic components 140, and a remaining portion of the openings 131 can still expose a portion of the first plurality of preformed conductive pillars 111 for mounting of external modules.

Next, a second plurality of preformed conductive pillars 145 are mounted onto the patterned shielding layer 130 and the first interconnection layer 120 to vertically align themselves with a second subset of the first plurality of preformed conductive pillars 111. The second plurality of preformed conductive pillars 145 may have a larger height than that of the at least one electronic component 140. To be more specific, FIG. 1H illustrates a perspective view of device structures during the mounting process, and FIG. 1I illustrates a sectional view of the device structures along line AA’ shown in FIG. 1H. In some embodiments, the second plurality of preformed conductive pillars 145 may have the same shape, configuration, material and mounting process as those of the first plurality of preformed conductive pillars 111, which will not be elaborated here.

Referring to FIG. 1I in conjunction with FIG. 1H, the second plurality of preformed conductive pillars 145 are aligned vertically and electrically connected with a second subset of the first plurality of preformed conductive pillars 111b. The electrical connection between the second plurality of preformed conductive pillars 145 and the second subset of the first plurality of preformed conductive pillars 111b may allow for various electrical paths within the interconnection device.

To be more specific, the second plurality of preformed conductive pillars 145 may be separated into two portions, i.e., a first portion 145a and a second portion 145b. The second subset of the first plurality of preformed conductive pillars 111b may further be separated into two portions, i.e., a first portion 111-i and a second portion 111-ii. The first portion of the second subset of the first plurality of preformed conductive pillars 111-i are covered by the patterned shielding layer 130, and the first portion of the second plurality of preformed conductive pillars 145a may be indirectly connected with the first portion of the second subset of the first plurality of preformed conductive pillars 111-i via the patterned shielding layer 130 therebetween. Therefore, the first portion of the second subset of the first plurality of preformed conductive pillars 111-i, the first portion of the second plurality of preformed conductive pillars 145a and the patterned shielding layer 130 may be electrically connected together, allowing common connection to a reference voltage such as a ground (GND) connection. The second portion of the second subset of the first plurality of preformed conductive pillars 111-ii are exposed form the openings 131 of the patterned shielding layer 130, and the second portion of the second plurality of preformed conductive pillars 145b may be directly connected with the second portion of the second subset of the first plurality of preformed conductive pillars 111-ii. It can be appreciated that the direct connection between the second portion of the second plurality of preformed conductive pillars 145b and the second portion of the second subset of the first plurality of preformed conductive pillars 111-ii may include direct contact, attachment via conductive adhesive, mounting via conductive pads 118, metallic bonding, etc. In this way, the second portion of the second subset of the first plurality of preformed conductive pillars 111-ii and the second portion of the second plurality of preformed conductive pillars 145b may build up an electrical path to transmit electrical signals therebetween. Furthermore, the at least one electronic component 140 may be electrically connected with the first subset of the first plurality of preformed conductive pillars 111a, which incorporate the at least one electronic component 140 within the interconnection device to form an integrated interconnection module.

In some embodiments, after the mounting of the second plurality of preformed conductive pillars 145, a grinding process may be conducted at top surfaces of the second plurality of preformed conductive pillars 145 such that their top surfaces can be flush with each other afterwards. Furthermore, a second plurality of conductive pads may be formed on the top surfaces of the second plurality of preformed conductive pillars 145.

Next, as shown in FIG. 1J, a second insulating layer is formed on the first insulating layer (that is, the first molding layer 115). In this embodiment, the second insulating layer may be a second molding layer 150. The second molding layer 150 encapsulates the second plurality of preformed conductive pillars 145 and the at least one electronic component 140. In some embodiments, the second molding layer 150 may be formed using a film assisted molding process, which is similar to the formation process of the first molding layer 115 illustrated in FIGS. 1C to 1E. In addition, the second molding layer 150 may have the same material as that of the first molding layer 115, which will not be elaborated here. The top surfaces of the second plurality of preformed conductive pillars 145 are exposed from a top surface of the second molding layer 150, thereby forming the second interconnection layer 152 on the first interconnection layer 120.

Next, as shown in FIG. 1K, solder bumps 160 are attached on the exposed top surfaces of the second plurality of preformed conductive pillars 145 for mounting the device onto an external electronic module. In this way, a substrate-less modular interconnection device with double-sided molding layers is formed. The modular interconnection device may be used to build up electrical connection paths between stacked electronic modules within a highly integrated package assembly. Since the modular interconnection device includes at least one electronic component 140, this allows for more efficient space utilization of the device by integrating additional electrical functionality in the modular interconnection device apart from electrical interconnections. As a result, the integration level of an electronic package utilizing this modular interconnection device can be significantly improved, and the electrical performance may also be enhanced. Furthermore, since the preformed conductive pillars 111, 145 are arranged in two layers of interconnection layers instead of being fabricated as taller integrated structures, their formation process may be more convenient and cost-effective.

In some embodiments, a plurality of the modular interconnection devices may be manufactured in a batch manner. For example, a plurality of the interconnection units may be manufactured in a strip level, and then the interconnection units can be singulated into a plurality of units or pieces each being a modular interconnection device. In this way, each of the interconnection devices may be used as a preformed interconnection module in a fabrication process of a highly integrated package assembly, which is a replacement for a conventional e-bar while interconnecting modules.

In some other embodiments, apart from the first plurality of preformed conductive pillars, a first interconnection layer may also include at least one electronic component. The at least one electronic component may be attached onto an adhesive layer before, after or simultaneously with mounting of the first plurality of preformed conductive pillars. In particular, the at least one electronic component within the first interconnection layer is encapsulated by a first insulating layer. A portion of the second plurality of preformed conductive pillars may be mounted above the at least one electronic component of the first interconnection layer. Alternatively, in some cases, no preformed conductive pillars may be mounted above the at least one electronic component of the first interconnection layer. The at least one electronic component of the first interconnection layer may expose its bottom pads from a bottom surface of the first molding layer to allow for electrical connection between the at least one electronic component and other modules. In this embodiment, both the first interconnection layer and the second interconnection layer incorporate the electronic component(s) within the interconnection layer. The so formed modular interconnection device allows for even more efficient space utilization and an enhanced integration level of an electronic package utilizing this modular interconnection device.

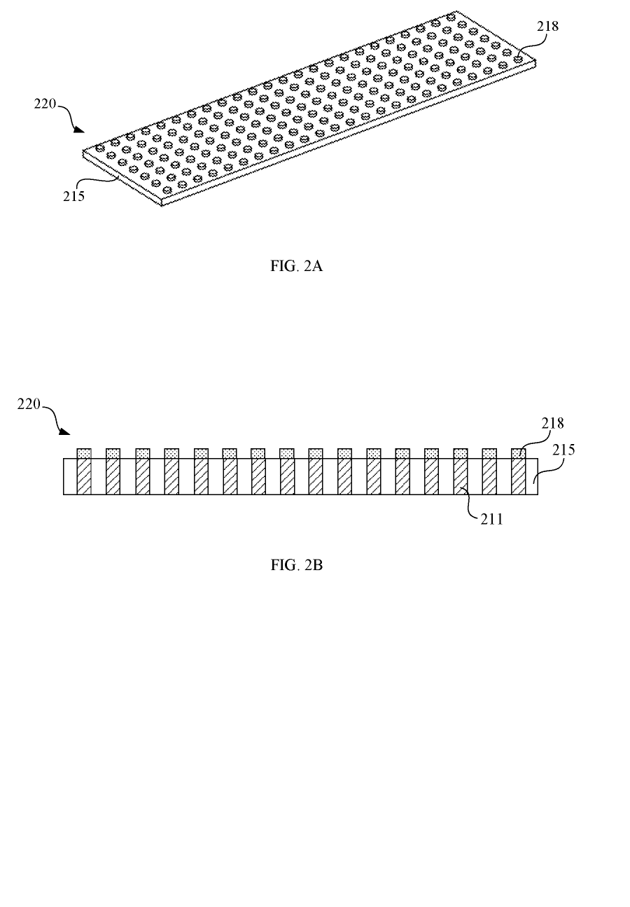

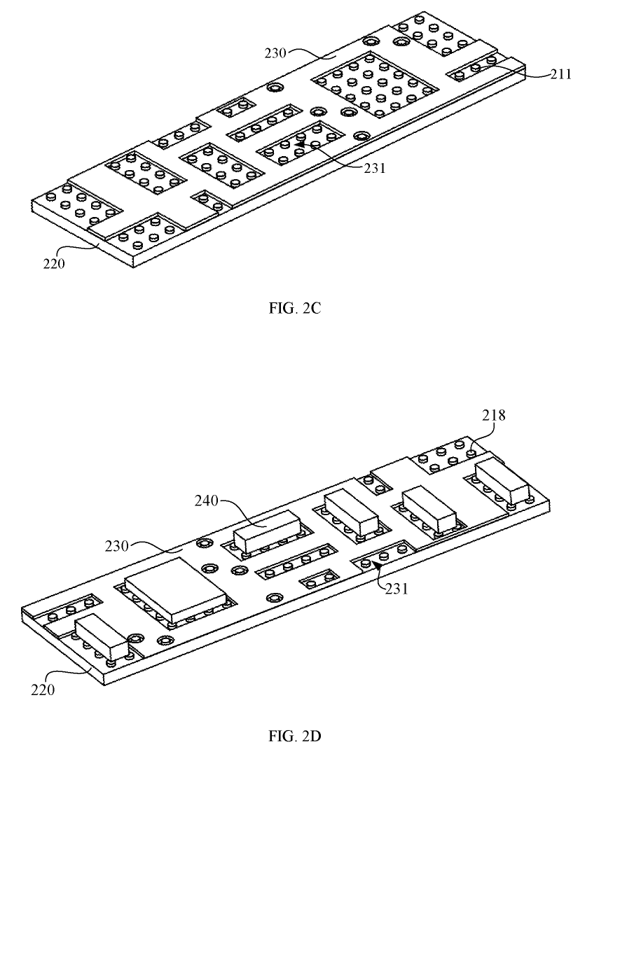

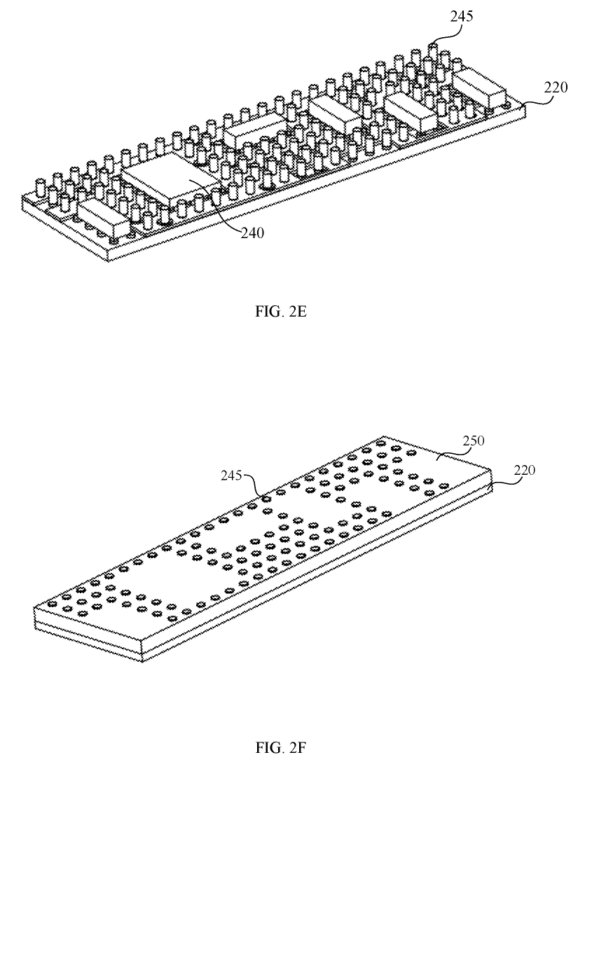

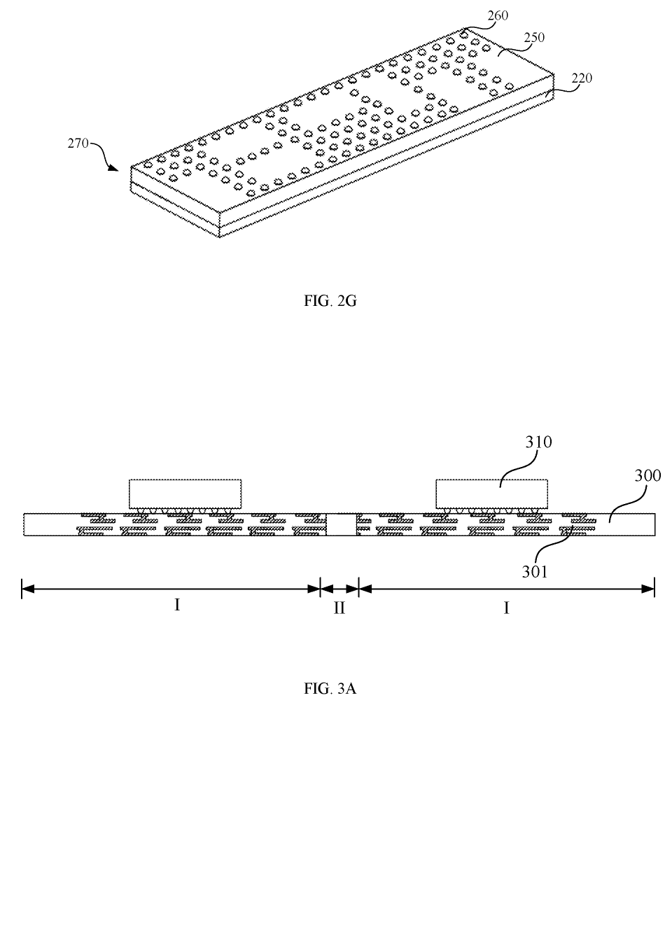

FIGS. 2A-2G illustrate various steps of a method for forming a modular interconnection device according to a second embodiment of the present application. The modular interconnection device has a structure and a forming process similar as the modular interconnection device shown in FIGS. 1A-1K, except that the first interconnection layer included within the modular interconnection device in FIGS. 2A-2G is provided as a substrate instead of the first interconnection layer 120 having a first molding layer 115 shown in FIGS. 1A-1K.

To be more specific, as shown in FIGS. 2A and 2B, a substrate 220 is provided. FIG. 2A illustrates a perspective view of the substrate 220, and FIG. 2B illustrates a sectional view of the substrate 220 shown in FIG. 2A. The substrate 220 includes a substrate base 215 and a first plurality of preformed conductive pillars 211 extending vertically through the substrate base 215. The substrate base 215 may serve as an insulating layer. The substrate base 215 may include silicon or another semiconductor material, a ceramic material or any other suitable materials. Bottom surfaces of the first plurality of preformed conductive pillars 211 are exposed from a bottom surface of the substrate base 215. Furthermore, a first plurality of conductive pads 218 may be formed on the top surfaces of the first plurality of preformed conductive pillars 211. The first plurality of preformed conductive pillars 211 may have the same shape, configuration and material as those of the first plurality of preformed conductive pillars 111 in FIG. 1A, which will not be elaborated here. In some other embodiments, apart from the first plurality of preformed conductive pillars 211, the substrate 220 may also include at least one electronic component pre-mounted within the substrate base 215. The substrate 220 may be a preformed structure fabricated through a preforming process. During the preforming process, the first plurality of preformed conductive pillars 211 may be formed as extending vertically through the substrate base 215 via various conventional fabrication processes of the conductive pillars.

Next, as shown in FIG. 2C, a patterned shielding layer 230 is formed on the substrate 220 (or more particularly, the substrate base 215). The patterned shielding layer 230 includes a plurality of openings 231 exposing a portion of the first plurality of preformed conductive pillars 211. Next, as shown in FIG. 2D, at least one electronic component 240 is mounted onto a first subset of the first plurality of preformed conductive pillars 211 through the openings 231 of the patterned shielding layer 230. Next, as shown in FIG. 2E, a second plurality of preformed conductive pillars 245 are mounted onto the patterned shielding layer 230 and the substrate 220 to vertically align themselves with a second subset of the first plurality of preformed conductive pillars 211. Next, as shown in FIG. 2F, a molding layer 250 is formed on the substrate 220 to encapsulate the second plurality of preformed conductive pillars 245 and the at least one electronic component 240. The front surfaces of the second plurality of preformed conductive pillars 245 are exposed from a top surface of the molding layer 245. Next, as shown in FIG. 2G, solder bumps 260 are attached on the exposed top surfaces of the second plurality of preformed conductive pillars 245 for mounting the device onto an external electronic module. In this way, a modular interconnection device 270 with a single-sided molding layer is formed. The structure and formation process of the modular interconnection device 270 may be similar to those of the modular interconnection device illustrated in FIGS. 1A-1K, which will not be elaborated here.

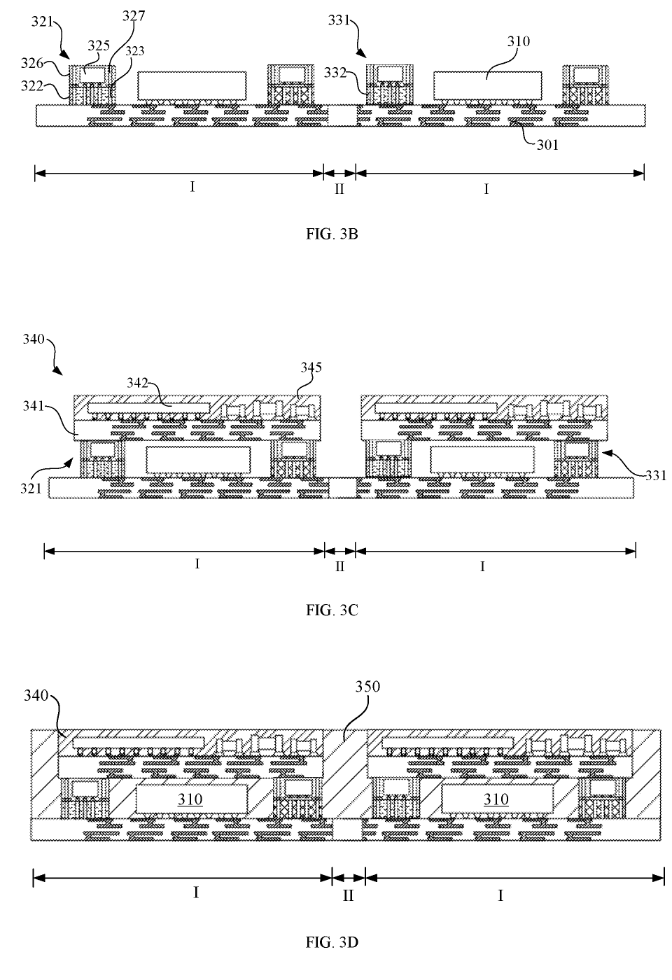

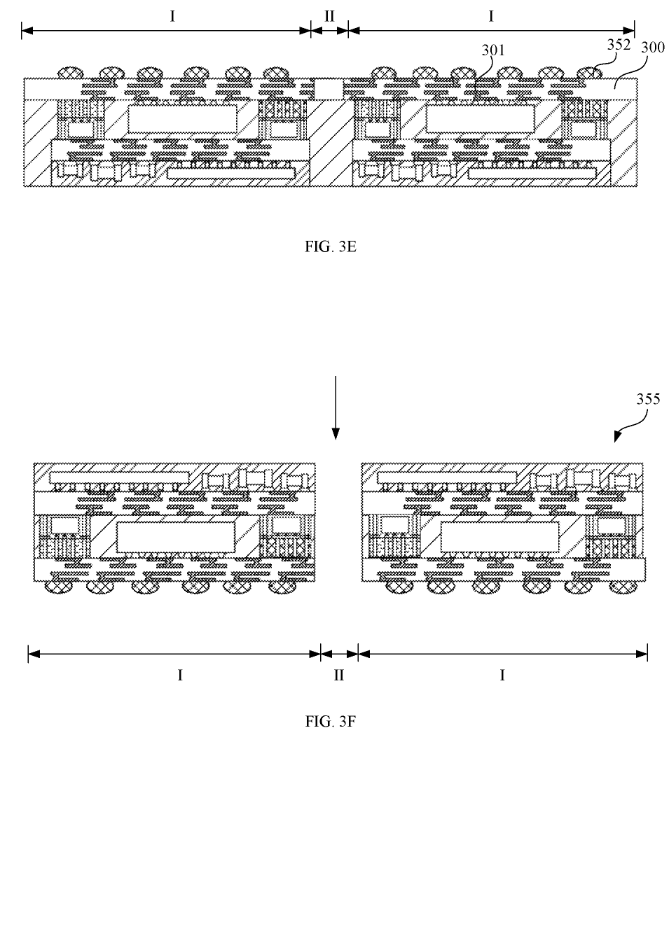

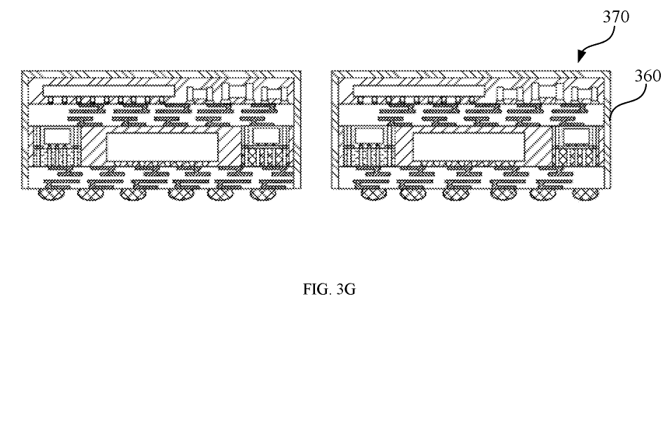

FIGS. 3A-3G illustrate various steps of a method for forming an electronic package assembly according to a third embodiment of the present application.

As shown in FIG. 3A, a substrate strip 300 is provided. The substrate strip 300 includes a plurality of substrate units I which may have the same layout and overall structure. In some other embodiments, the substrate units I may be different in layout and overall structure, which can also be processed using the method of the present application. After a subsequent packaging process which will be detailed below, the substrate units I can be singulated from the substrate strip 300 to form a plurality of pieces each being an individual electronic package assembly. It can be appreciated that the following processes are described with reference to two substrate units I of the substrate strip 300 as an example, and the same or similar processes can be implemented to a portion or all of the substrate units I of the substrate strip 300.

The substrate strip 300 includes a front surface facing upward in the direction shown in FIG. 3A, and a back surface opposite to the front surface. In some embodiments, the substrate strip 300 may be made of silicon or any other semiconductor materials, or may include a printed circuit board (PCB), a carrier substrate, a ceramic substrate, a laminate interposer, a strip interposer, a leadframe, or other suitable substrates. In some examples, the substrate strip 300 may include interconnect wires 301, redistribution layers or structures having one or more dielectric layers and one or more conductive layers between and through the dielectric layers. Thus, various components and other structures on either one surface or both surfaces of the substrate strip 300 may be electrically coupled with each other. In some embodiments, a plurality of conductive pads can be formed on the front surface and/or the back surface of the substrate strip 300 for mounting the various components thereon. It can be appreciated that the plurality of conductive pads may be exposed portions of interconnect wires 301 formed within the substrate strip 300.

The substrate strip 300 also includes a plurality of saw regions II, each of which is located between two adjacent substrate units I, thus connecting the plurality of substrate units I as the substrate strip 300. The saw regions II may be dummy zones without functional modules, which may be designed for singulation in a subsequent process. It can be appreciated that both the saw regions II and the substrate units I can be formed in situ within the substrate strip 300.

Still referring to FIG. 3A, at least one electronic module 310 is attached onto the front surface of each of the substrate units I via solder bumps or in other suitable manners, thus forming electrical connection between the interconnect wires 301 within the substrate strip 300 and the at least one electronic module 310. In some embodiments, the electronic module 310 may be a semiconductor chip or a semiconductor package. To be more specific, the electronic module 310 may have a relatively large thickness, for example, and the electronic module 310 may be a thick semiconductor die or an electronic package stack with a multi-layer structure. It can be appreciated that more electronic modules 310 may be mounted onto the front surface of each of the substrate units I. The structures, layouts, and types of the electronic modules 310 mounted on the various substrate units I may be identical or different from one another. In addition, no electronic module 310 is mounted onto the saw regions II to avoid impacting the singulation of the substrate strip 300.

Next, as shown in FIG. 3B, at least one modular interconnection device is mounted onto the front surface of the each of the substrate units I via solder bumps or conductive pads, for example. In some embodiments, the modular interconnection device may be a substrate-less interconnection device 321 with double-sided molding layers, which is formed using the steps shown in FIGS. 1A-1K. To be more specific, the substrate-less interconnection device 321 includes a first interconnection layer having a first insulating layer 322 and a first plurality of preformed conductive pillars 323 extending vertically through the first insulating layer 322, and a second interconnection layer having a second insulating layer 326 and a second plurality of preformed conductive pillars 327 extending through the second interconnection layer 326. The first insulating layer 322 and the second insulating layer 326 are both molding layers. The second interconnection layer further has at least one electronic component 325 formed within the second insulating layer 326 and electrically connected with a first subset of the first plurality of preformed conductive pillars 323, and the second plurality of preformed conductive pillars 327 are aligned vertically and electrically connected with a second subset of the first plurality of preformed conductive pillars 323. In some embodiments, the modular interconnection device may also be an interconnection device 331 with a single-sided molding layer, which is formed using the steps shown in FIGS. 2A-2G. The modular interconnection device 331 is similar to the interconnection device 321 with double-sided molding layers except that the first interconnection layer 332 of the modular interconnection device 331 is a substrate and does not include a molding layer, and the first insulating layer included within the first interconnection layer 332 is a substrate base. Furthermore, the modular interconnection devices 321, 331 may have a greater height than the thickness of the electronic module(s) 310. The modular interconnection devices 321, 331 may be preformed and used as highly integrated e-bar modules for the purpose of electrical connection in the electronic package assembly. In addition, the modular interconnection devices 321, 331 may be grasped and mounted onto the substrate units I in a batch manner through a tray supply.

As shown in FIG. 3B, the modular interconnection devices 321, 331 may be mounted onto respective front surfaces of the substrate units I. In some embodiments, each of the modular interconnection devices 321, 331 may be arranged at a periphery of the corresponding substrate unit I and surrounding the at least one electronic module 310 on the substrate unit I. In addition, at least one of the modular interconnection devices mounted on the substrate units I is the substrate-less interconnection device 321 with double-sided molding layers or the interconnection device 331 with a single-sided molding layer. In some embodiments, as shown in FIG. 3B, the modular interconnection devices mounted on the substrate units I include both the substrate-less interconnection device 321 with double-sided molding layers and the interconnection device 331 with a single-sided molding layer. In some other embodiments, all the modular interconnection devices mounted on each substrate unit I are of the same type, for example, either all being substrate-less interconnection device 321 with double-sided molding layers or all being interconnection devices 331 with a single-sided molding layer. It can be appreciated that the type, the number and the layout of the plurality of modular interconnection devices mounted on each substrate unit I may vary according to actual needs of the electronic package assembly to be formed. Next, additional solder bumps may be attached on the top surfaces of the modular interconnection devices 321, 331.

Next, as shown in FIG. 3C, an additional package 340 may be mounted onto top surfaces of the modular interconnection devices 321, 331 via solder bumps, for example. The additional package 340 may include a package substrate 341, at least one electronic device 342 mounted on the package substrate 341, and a molding layer 345 encapsulating the package substrate 341 and the at least one electronic device 342.

Next, as shown in FIG. 3D, an additional molding layer 350 is formed on the substrate strip 300 to encapsulate the at least one electronic module 310, the modular interconnection devices 321, 331 and the additional package 340. To be more specific, the additional molding layer 350 may be formed using an injection molding process, which covers the front surface of the substrate units I and the saw regions II, respective surfaces of the at least one electronic module 310, respective surfaces of the modular interconnection device 321, 331 and the additional package 340 for encapsulation. In some other embodiments, the additional molding layer 350 may be formed using other various molding technologies, including a transfer molding process, a compression molding process or a film-assisted molding (FAM) process, for example. In some embodiments, the additional molding layer 350 may include the same material as, or a different material from with the molding layer within the additional package 340.

In some other embodiments, the package substrate 341 and the at least one electronic device 342 may first be mounted onto the modular interconnection device 321, 331. Then the additional molding layer 350 may be formed to encapsulate the at least one electronic device 342 and the package substrate 341 together with the at least one electronic module 310 and the modular interconnection devices 321, 331 as an integrated molding piece.

Next, as shown in FIG. 3E, extra solder bumps 352 may be formed onto back surfaces of the substrate units I for mounting the electronic package assembly onto external electronic device.

Next, as shown in FIG. 3F, a singulation process may be conducted at the saw regions II to remove the saw regions II and the additional molding layer 350 formed thereon, such that the substrate units I with structures thereon are singulated from the substrate strip 300 to form electronic package units 355 in a batch. The singulation process may be implemented using a laser blade, which may precisely control the positions of singulation, thereby avoiding exposure of the preformed conductive pillars within the modular interconnection device 321, 331 from the additional molding layer 350.

Next, as shown in FIG. 3G, a shielding layer 360 may be formed on exposed surfaces of the electronic package units 355, i.e., surfaces except for bottom surfaces of the substrate units I intended for mounting the device on external modules. The shielding layer 360 may help to protect the other parts of the device from electromagnetic interferences. The shielding material may include metals, carbons, ceramics, cement, conducting polymers, etc. As such, electronic package assemblies 370 are formed.

The electronic package assembly 370 uses the modular interconnection devices 321, 331 as highly integrated e-bar modules, such that the additional package 340 and the substrate unit I are interconnected with each other to form an integrated circuit system. Since the modular interconnection device 321, 331 includes at least one electronic component, this allows for more efficient space utilization of the electronic package assembly by integrating additional electrical functionality of the modular interconnection devices through the embedded electronic component(s) apart from electrical interconnections. As a result, the integration level of the electronic package assembly 370 can be significantly improved, and the electrical performance may also be enhanced. In addition, the modular interconnection devices 321, 331 can be used as modular e-bar modules, which are convenient for electronic module designs and manufacturing, thereby reducing production costs and improving efficiency.

While the exemplary modular interconnection device and the method for forming the same of the present application is described in conjunction with corresponding figures, it will be understood by those skilled in the art that modifications and adaptations to the modular interconnection device and the method for forming the same may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A modular interconnection device, comprising:
a first interconnection layer having a first insulating layer and a first plurality of preformed conductive pillars extending vertically through the first insulating layer with respective bottom surfaces exposed from a bottom surface of the first insulating layer; and
a second interconnection layer formed on a top surface of the first interconnection layer, the second interconnection layer having a second insulating layer and a second plurality of preformed conductive pillars extending through the second interconnection layer with respective top surfaces exposed from a top surface of the second insulating layer, wherein the second interconnection layer further has at least one electronic component formed within the second insulating layer and electrically connected with a first subset of the first plurality of preformed conductive pillars, and wherein the second plurality of preformed conductive pillars are aligned vertically and electrically connected with a second subset of the first plurality of preformed conductive pillars.

2. The modular interconnection device of claim 1, further comprising:
a patterned shielding layer formed between the first interconnection layer and the second interconnection layer, and for indirectly connecting a portion of the second plurality of preformed conductive pillars with a portion of the second subset of the first plurality of preformed conductive pillars, and wherein the patterned shielding layer comprises a plurality of openings allowing direct connection between a remaining portion of the second plurality of preformed conductive pillars and a remaining portion of the second subset of the first plurality of preformed conductive pillars.

3. The modular interconnection device of claim 1, wherein the first insulating layer comprises a first molding layer encapsulating the first plurality of preformed conductive pillars, and the second insulating layer comprises a second molding layer encapsulating the second plurality of preformed conductive pillars and the at least one electronic component.

4. The modular interconnection device of claim 1, wherein the first interconnection layer comprises a substrate, and the first plurality of preformed conductive pillars are preformed within the substrate, the first insulating layer comprises a substrate base; and the second insulating layer comprises a second molding layer encapsulating the second plurality of preformed conductive pillars and the at least one electronic component.

5. The modular interconnection device of claim 1, wherein the electronic component comprises a semiconductor die or an integrated circuit chip.

6. The modular interconnection device of claim 1, wherein the second plurality of preformed conductive pillars have a larger height than that of the at least one electronic component.

7. The modular interconnection device of claim 1, further comprising: solder bumps attached on the exposed top surfaces of the second plurality of preformed conductive pillars.

8. The modular interconnection device of claim 1, wherein the first interconnection layer further comprises at least one electronic component.

9. A method for forming a modular interconnection device, comprising:
providing a carrier;
attaching a first plurality of preformed conductive pillars on a front surface of the carrier;
forming a first molding layer on the carrier to encapsulate the first plurality of preformed conductive pillars but expose their respective bottom surfaces;
mounting at least one electronic component onto a first subset of the first plurality of preformed conductive pillars;
vertically aligning and connecting a second plurality of preformed conductive pillars with a second subset of the first plurality of preformed conductive pillars; and
forming a second molding layer on the first molding layer to encapsulate the second plurality of preformed conductive pillars and the at least one electronic component but expose respective top surfaces of the second plurality of preformed conductive pillars.

10. The method of claim 9, after forming a first molding layer and before mounting at least one electronic component, the method further comprising:
forming a patterned shielding layer on the first molding layer, wherein the patterned shielding layer comprises a plurality of openings exposing a portion of the first plurality of preformed conductive pillars.

11. The method of claim 9, wherein forming a first molding layer on the carrier comprises forming the first molding layer via a film assisted molding technique.

12. The method of claim 9, wherein forming a second molding layer on the first molding layer comprises forming the second molding layer via a film assisted molding technique.

13. The method of claim 9, after forming a second molding layer on the first molding layer, the method further comprising:
removing the carrier from the first molding layer.

14. The method of claim 9, before forming a first molding layer on the carrier, the method further comprising: attaching at least one electronic component onto the carrier.

15. A method for forming a modular interconnection device, comprising:
providing a substrate having a substrate base and a first plurality of preformed conductive pillars extending vertically through the substrate base with respective bottom surfaces exposed from a bottom surface of the substrate base;
mounting at least one electronic component onto a first subset of the first plurality of preformed conductive pillars;
vertically aligning and connecting a second plurality of preformed conductive pillars with a second subset of the first plurality of preformed conductive pillars; and
forming a molding layer on the substrate to encapsulate the second plurality of preformed conductive pillars and the at least one electronic component but expose respective top surfaces of the second plurality of preformed conductive pillars.

16. The method of claim 15, before mounting at least one electronic component, the method further comprising:
forming a patterned shielding layer on the substrate base, wherein the patterned shielding layer comprises a plurality of openings exposing a portion of the first plurality of preformed conductive pillars.
